(19) United States
(12) Patent Application Publication
(10) Pub. No.: US 2025/0133730 A1
(43) Pub. Date: Apr. 24, 2025

(54) 3D MEMORY CELL ARRAY WORD LINE CONNECT AREA

(71) Applicant: Applied Materials, Inc., Santa Clara, CA (US)

(72) Inventors: WanGee Kim, Dublin, CA (US); Michel Frei, Palo Alto, CA (US); Mahendra Pakala, Saratoga, CA (US); Ellie Y. Yieh, San Jose, CA (US)

(21) Appl. No.: 18/919,189

(22) Filed: Oct. 17, 2024

Related U.S. Application Data
(60) Provisional application No. 63/591,710, filed on Oct. 19, 2023.

(51) Int. Cl. H10B 12/00

(52) U.S. Cl. CPC H10B 12/488; H10B 12/03

(57) ABSTRACT

This specification describes technologies for creating and coupling word lines of a 3D memory cell array to corresponding word lines of a word line connect area. One aspect is a method that includes positioning a memory cell array on a substrate adjacent to a word line connect area, the word line connect area comprising a plurality of layers, the plurality of layers alternating between a first material and a second material; replacing at least a portion of the layers of the first material with a third material; and replacing at least a portion of the layers of the second material with a fourth material, wherein the fourth material forms word lines within the word line connect area and is electrically coupled to memory cell word lines within the memory cell array.

### CROSS-REFERENCE TO RELATED APPLICATIONS

This application claims the benefit under 35 U.S.C. § 119(e) of the filing date of U.S. Patent Application No. 63/591,710, which was filed on Oct. 19, 2023, and which is incorporated here by reference.

### BACKGROUND

This specification relates to semiconductor devices, systems, processes, and equipment. Conventionally, memory cells of a memory device have been arranged in two dimensional rows, e.g., to form an A×B arrangement of memory cells. Each memory cell can store a binary bit value of logical zero or one. The cells in the row are electrically coupled by a bit line. Additionally, each cell is electrically coupled to a word line. Each intersection of bit line and word line can define a memory address for a particular memory cell. To further increase bit density, some memory devices are formed from rows of memory cells that are stacked in three-dimensions to form an A×B×C memory cell array.

### SUMMARY

This specification describes technologies for coupling word lines of a 3D memory cell array to corresponding word lines of a word line connect area. This specification further describes a process for fabricating word lines within the word line connect area. In particular, a memory cell array, for example, a dynamic random access memory (DRAM) memory cell array can be fabricated and then integrated with a word line connect region in which word lines can be formed tier by tier and electrically coupled to the word lines of the memory cell array. In some implementations, a word line connect area is fabricated in a particular layout of alternating layers of two different materials. Using combinations of etching and deposition processes, the layers of the word line connect area can be transformed into alternating layers of materials having dry etch selectivity. Further operations can be performed on the word line connect area to form tier by tier word lines to electrically couple each memory cell word line to an external electrical conduction pathway.

In general, one innovative aspect of the subject matter described in this specification can be embodied in a method. The method includes positioning a memory cell array on a substrate adjacent to a word line connect area, the word line connect area comprising a plurality of layers, the plurality of layers alternating between a first material and a second material; replacing at least a portion of the layers of the first material with a third material; and replacing at least a portion of the layers of the second material with a fourth material, wherein the fourth material forms word lines within the word line connect area and is electrically coupled to memory cell word lines within the memory cell array.

In general, another innovative aspect of the subject matter described in this specification can be embodied in a layout structure for fabricating a memory device. The layout structure includes a substrate base; a word line connect area formed on a first portion of the substrate, the word line connect area comprising a plurality of layers, the plurality of layers alternating between a first material and a second material, the word line connect area further comprising one or more slits through the plurality of layers, wherein each of the one or more slits exposes a surface of each layer in the plurality of layers; and a 3D memory cell array comprising a plurality of memory cells arranged along x, y, and z axes, the 3D memory cell array being positioned on a second portion of the substrate adjacent to the word line connect area.

In general, another innovative aspect of the subject matter described in this specification can be embodied in a method. The method includes positioning a memory cell array on a substrate adjacent to a word line connect area, the word line connect area comprising a plurality of layers, the plurality of layers alternating between a first material and a second material; forming one or more slits in the word line connect area through the plurality of layers, wherein each of the one or more slits exposes a surface of each layer in the plurality of layers of the word line connect area; recessing at least a portion of each layer of the first material using a selective etching, wherein each layer is accessed using the one or more slits; recessing portions of the gate oxide layer adjacent to the recessed portions of the layers of the first material, wherein the recessed portions of the gate oxide layer expose a surface of a memory cell word line region in the memory cell array; recessing portions of the memory cell word line region in the memory cell array; reducing a dimension of at least a portion of layers of the second material; depositing layers of a third material in the recessed portions of the memory cell word line region and in recessed spaces of the first material; recessing at least a portion of each layer of the second material; recessing portions of the gate oxide layer of the memory cell array adjacent to the second material and to respective memory cell word lines of the memory cell array; and depositing layers of the fourth material in recessed spaces of the second material to form word lines within the word line connect area, each word line being electrically coupled to a corresponding memory cell word line.

The subject matter described in this specification can be implemented in these and other embodiments so as to realize one or more of the following advantages. The layout and processes described in this specification facilitate the formation of tier by tier word line connections to memory cells of a 3D memory cell array that can manage word line connections as bit density, and thus memory cell array size, increases. This allows for tier by tier word line connections within a word line connect area having a specified geometric size that is compact and precise. Furthermore, by separately fabricating the memory cell array and the word line connect area and then integrating the two, manufacturing processes are simplified. Modifying a standard DRAM word line connect stack to a stack having materials that have dry etch selectivity allows for more precise creation of tier by tier word line connections to the memory cell array.

### BRIEF DESCRIPTION OF THE DRAWINGS

FIG. 1 shows a diagram representing an example DRAM memory cell.

FIG. 2 shows a diagram representing an example memory cell array.

FIG. 3 is a flow diagram of an example process for fabricating and coupling word lines to a memory cell array.

FIG. 4 is a diagram of an example layout of a memory cell array and word line connect area.

FIG. 5 is a diagram of a memory cell array integrated with a word line connect area.

FIG. 6 is a diagram of the memory cell array integrated with a word line connect area having open slits and including a cross-sectional view of a magnified region.

FIG. 7 is a diagram of the memory cell array integrated with a word line connect area including a cross-sectional view of a magnified region with recessed SiGe layers.

FIG. 8 is a diagram of the memory cell array integrated with a word line connect area including a cross-sectional view of a magnified region with gate oxide recesses.

FIG. 9 is a diagram of the memory cell array integrated with a word line connect area including a cross-sectional view of a magnified region with cell word line recesses.

FIG. 10 is a diagram of the memory cell array integrated with a word line connect area including a cross-sectional view of a magnified region with reduction of silicon layers.

FIG. 11 is a diagram of the memory cell array integrated with a word line connect area including a cross-sectional view of a magnified region with added oxide layers.

FIG. 12 is a diagram of the memory cell array integrated with a word line connect area including etched word line staircase openings.

FIG. 13 is a diagram of the memory cell array integrated with a word line connect area having open slits including a cross-sectional view of a magnified region.

FIG. 14 is a diagram of the memory cell array integrated with a word line connect area including a cross-sectional view of a magnified region with recessed silicon layers.

FIG. 15 is a diagram of the memory cell array integrated with a word line connect area including a cross-sectional view of a magnified region with gate oxide recesses.

FIG. 16 is a diagram of the memory cell array integrated with a word line connect area including a cross-sectional view of a magnified region with conductive word line deposition.

Like reference numbers and designations in the various drawings indicate like elements.

### DETAILED DESCRIPTION

The present specification describes technologies for coupling word lines of a 3D memory cell array to corresponding word lines of a word line connect area. The present specification further describes technologies for fabricating word lines within the word line connect area to provide tier by tier word lines corresponding to rows of the 3D memory cell array.

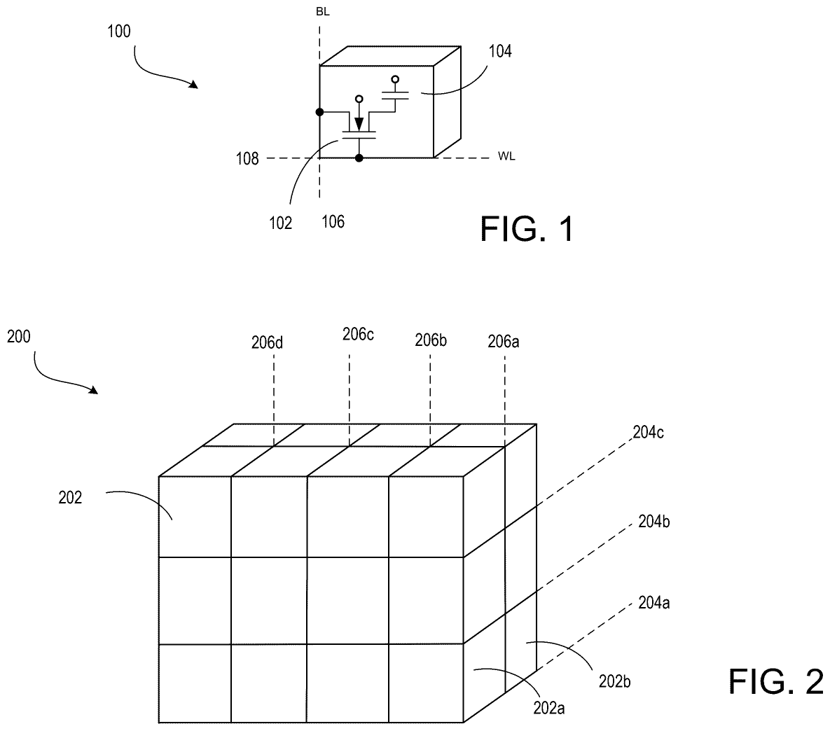

FIG. 1 shows a diagram representing an example DRAM memory cell 100. The DRAM memory cell 100 is composed of a transistor 102 and a capacitor 104 pair that is configured to store one bit of data. In some implementations, the transistor and capacitor can be formed using metal-oxide-semiconductor (MOS) technology. The state of the capacitor as charged or discharged corresponds to the logical zero or one for the bit of information.

The internal structure illustrated is provided as an example representation. Other memory cell configurations are possible. For example, in some alternative implementations, the DRAM memory cell can be formed from two transistors without a capacitor. Furthermore, while DRAM memory cells and arrays are described, the techniques may be applicable to other types of memory cells formed into 3D arrays.

The memory cell 100 is electrically coupled to a bit line 106 and a word line 108. The bit line 106 is electrically coupled to the source terminal of the transistor 102 and the word line is electrically coupled to the gate terminal of the transistor 102. Read operations to read the state of the capacitor and write operations to set the state of the capacitor can be governed by selectively sending or receiving electricity along the bit line and word line.

FIG. 2 shows a diagram of an example three-dimensional (3D) memory cell array 200. The 3D memory cell array 200 is formed from a collection of memory cells 202 arranged along three dimensions, e.g., the array can have memory cells arranged in a cube having a height, width, and depth of memory cells. Each memory cell can be, for example, a DRAM memory cell 100 as shown in FIG. 1. In the example shown in FIG. 2, the 3D memory cell array is a 3×4×2 array of 24 memory cells. A large number of memory cells can be formed into an array of a memory device, e.g., a DRAM memory device having millions to billions of memory cells.

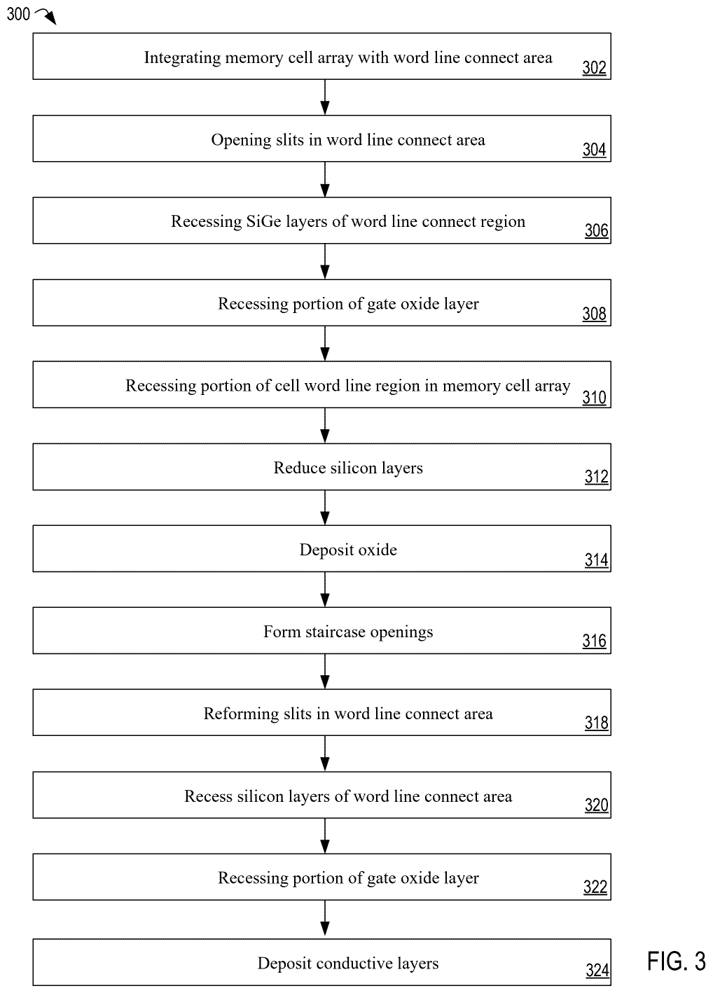

In the example 3D memory cell array 200, word lines 204a-c electrically couple memory cells 202 on a first axis while bit lines 206a-d electrically couple memory cells 202 along a second, perpendicular axis. Thus, for example, word line 204a is coupled to the gate terminals of memory cell transistors in memory cells 202a and 202b. As memory cell arrays increase in size there are increased word lines that need to be externally coupled within a relatively constrained geometric region. These external couplings typically need to be fabricated separate from the memory cell array due to the complexity of multi-layer and multi-material fabrication. FIGS. 3-16 describe a layout for a word line connect area in which the word line couplings can be fabricated and joined to corresponding word lines of a fabricated 3D memory cell array.

FIG. 3 is a flow diagram of an example process 300 for fabricating and coupling word lines to a memory cell array. The example process 300 can be carried out using one or more different semiconductor fabrication components and can include wet etching, dry etching, and deposition operations.

The process 300 includes integrating a fabricated 3D memory cell array with a word line connect area (302). For example, the 3D memory cell array can be positioned on a substrate adjacent to a multi-layered word line connect area. The 3D memory cell array is positioned such that the word lines of the 3D memory cell array end adjacent to a surface face of the word line connect area. One or more outer surfaces of the 3D memory cell array, including the surface at the end of the word lines, is coated with an oxide layer referred to as “gate oxide” that may be formed by thermal oxidation of silicon to form silicon dioxide. Within the 3D memory cell array, each memory cell can be partially or completely surrounded by a gate oxide layer. Furthermore, rows of memory cells can be separated from rows above and below by an oxide layer (e.g., silicon dioxide SiO₂).

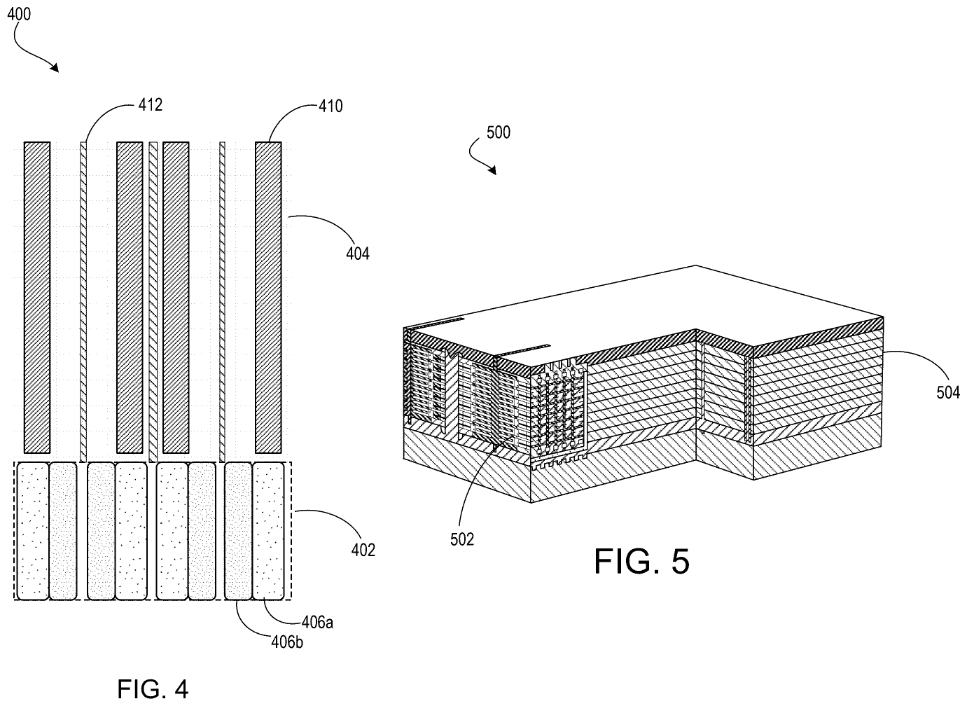

FIG. 4 is a diagram of an example layout 400 of a memory cell array and word line connect area. FIG. 5 is an isometric view 500 of a memory cell array 502 integrated with a word line connect area 504. Layout 400 can represent a top view of a portion of the memory cell array 502 and word line connect area 504 of FIG. 5. The layout 400 includes a single row of memory cells 402 from the memory cell array and a region representing the word line connect area 404. In particular, the memory cells 402 specifically illustrate four separate memory cells each having a capacitor portion 406a and a transistor gate and memory cell word line portion 406b. Thus, in the layout illustration there are four separate memory cells in the row of memory cells 402.

As shown in FIG. 5, the memory cells 402 are part of a larger 3D memory cell array 502. The memory cell array 502 is positioned next to the word line connect area 504. The word line connect area 504 is composed of multiple stacked layers. In some implementations, the multiple stacked layers are composed of alternating layers of silicon and a silicon alloy such as silicon germanium, SiGe, as described in greater detail below.

To provide access to the multiple layers within the word line connect area and each memory cell column, slits can be formed within the word line connect area 504 to expose the multiple layers. As shown in FIG. 4, the slits 410 are shown as aligned with the capacitor portion of each memory cell, which allows operations to be performed on the layers of the word line connect area coupled to the memory cell array word lines. In some implementations, additional isolation structures 412 can be added in the word line connect area and extended through the multiple layers of the word line connect area 504. For example, the word line connect area can be fabricated with insulating areas separating regions of the word line connect area coupled to each column of memory cells in the memory cell array.

As shown in FIG. 3, the process 300 includes opening up the slits in the word line connect area (304). For example, an etching operation can be performed on the word line connect area to form a channel or trench extending through the multiple layers of the word line connect area. The etching process can be selective, for example, so that alternating etch operations are performed to remove layers of differing material. In some implementations, because SiGe is not selectable in a dry etch operation, a wet etching operation is performed to remove the layers of the word line connect area to form the slits. Wet etching is a process for selectively removing material, e.g., from layers deposited onto a wafer substrate. Wet etching uses liquid chemical etchants to remove material. Masks can be applied to a surface to define the surface to be etched. For example, a mask can be applied that only exposes the region corresponding to the slits to be opened within the word line connect area. The liquid etchant dissolves the material being etched. In some implementations, the etchant is selective to particular materials such that the etchant may need to be switched to etch layers of different materials. In other implementations, a single etchant can be used to remove the material of both the silicon and SiGe layers of the word line connect area. Wet etching may be isotropic to some degree such that the slits formed in the word line connect area are not entirely uniform.

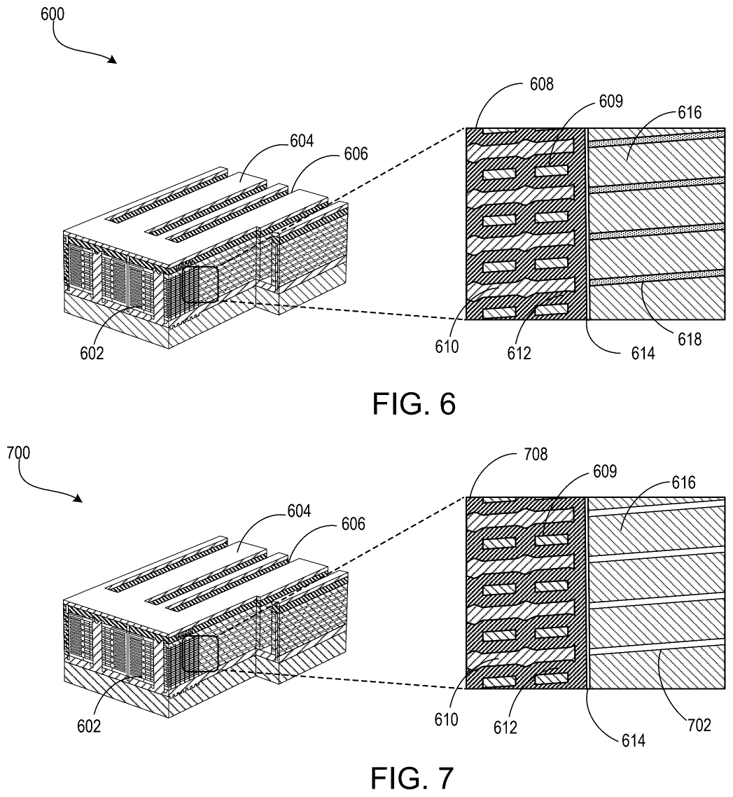

FIG. 6 is a diagram 600 of a memory cell array 602 integrated with a word line connect area 604 having open slits 606 and including a cross-sectional view of a magnified region 608 including a portion of the memory cell array 602 and multiple layers of the word line connect area 604. As illustrated with respect to the layout of FIG. 4, the open slits 602 extend through the multiple layers of the word line connect area 604 and are aligned with the capacitor portion of each column of memory cells.

The magnified region 608 illustrates the layers of memory cells and the layers of material in the word line connect area. In particular, eight memory cells 609 are illustrated in the magnified region in four rows of two memory cells. Each row of memory cells is separated by an oxide layer 610, e.g., SiO₂. The memory cells 609 are positioned, and the cross section taken, so that the memory cells represent the transistor gate and cell word line 612 portion of the memory cells. The capacitor portion of each memory cell, not shown, is positioned behind the illustrated memory cells, i.e., perpendicular to the cross section.

The memory cells 609 shown in a given row are coupled to the same memory cell word line 612. Additionally, as formed in the fabrication process, the word lines of all rows are coupled together as the oxide layer 610 does not extend to the edge facing the word line connect area 604. The memory cell word line 612 is formed of a conductive material, which can be a metal or other conductive/semiconductive material, for example, the memory cell word line 612 can be formed from titanium nitride (TiN), tungsten (W), molybdenum (Mo), or ruthenium (Ru). A gate oxide layer 614 separates the portion of the memory cell array 602 and the word line connect area 604.

The word line connect area 604 is composed of multiple layers of alternating materials. In particular, the word line connect area 604 includes multiple alternating layers of silicon 616 and SiGe 618. Because of the slits etched in the word line connect area 604, each of the alternating layers are adjacent to the slit channels and are accessible, e.g., through etching or deposition operations as described in greater detail below.

As shown in FIG. 3 the process 300 includes recessing the SiGe layers of the word line connect region (306). In particular, a wet etching composition selected for SiGe can be introduced into the slits formed in the word connect region. The selective wet etching, targeted to dissolve only SiGe, recesses the SiGe layers on each side of the slit while leaving the silicon layers unaffected.

FIG. 7 is a diagram 700 of the memory cell array 602 integrated with the word line connect area 604 including a cross-sectional view of a magnified region 708 with recessed SiGe layers. In diagram 700 the word connect area 604 includes recessed layers 702 illustrated in both the word line connect area 604 and the magnified region 708. The gate oxide layer 614 and silicon layers 616 are unchanged.

As shown in FIG. 3, the process 300 includes recessing a portion of the gate oxide layer (308). In particular, a portion of the gate oxide layer of the memory cell array is now exposed by the recession of the SiGe layers. The exposed portion of the gate oxide layer can then be selectively etched, for example, using a wet etching process that has a composition selected to etch the exposed gate oxide layer without etching the silicon layers of the word line connect area.

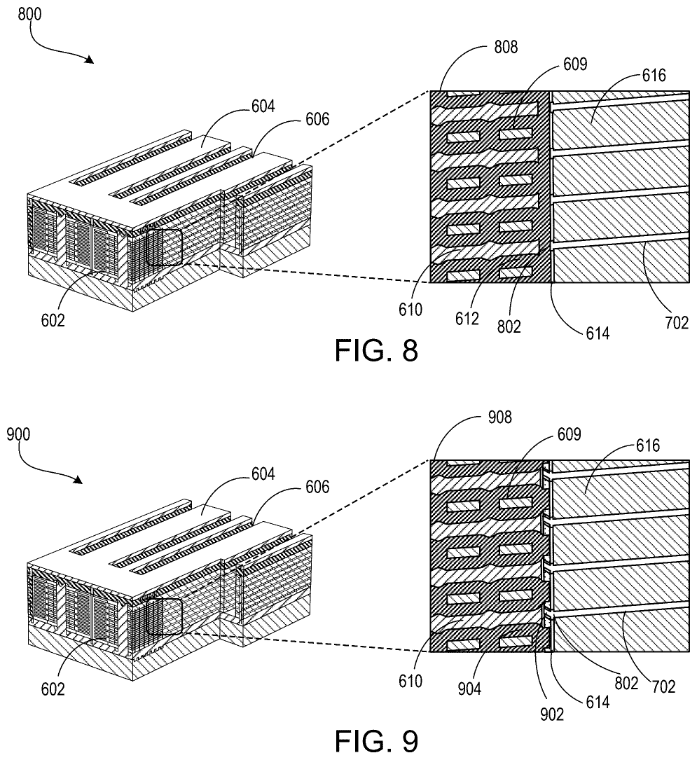

FIG. 8 is a diagram 800 of the memory cell array 602 integrated with the word line connect area 604 including a cross-sectional view of a magnified region 808 with gate oxide recesses 802. In diagram 800, the magnified region 808 illustrates openings formed in the gate oxide layer 614 that are aligned with the recessed layers 702 that were previously filled by the SiGe layers in the word line connect area 604.

As shown in FIG. 3, the process 300 includes recessing a portion of the memory cell word line region in the memory cell array (310). As described above, the conductive material of the memory cell word lines joins each of the cell word line rows since the oxide layer does not extend all of the way to the gate oxide layer. To electrically separate each row of memory cells in the memory cell array, a portion of the conductive material in the memory cell array is recessed. Access to the region to be recessed is provided by the openings in the gate oxide layer recessed at step 308. In some implementations, a wet etching operation can be performed that selectively removes conductive material from the exposed portions of the memory cell word lines without removing different materials from other layers.

FIG. 9 is a diagram 900 of the memory cell array 602 integrated with the word line connect area 604 including a cross-sectional view of a magnified region 908 with cell word line recesses 902. The magnified region 908 illustrates recesses 902 corresponding to portions of the memory cell word lines as aligned with the openings 802 formed in the gate oxide layer 804 and further aligned with the recessed layers 702 that were previously filled by the SiGe layers in the word line connect area 604. Additionally, the cell word line recesses 902 isolate individual cell word lines 904 from the cell word lines above or below the adjacent oxide layers 610.

As shown in FIG. 3, the process 300 includes reducing the thickness of the silicon layers in the word line connect area (312). As illustrated in FIG. 6, the original SiGe layers were substantially thinner in the illustrated cross-section than the thickness of the silicon layers. The silicon layers are thinned to provide additional space for new material to be deposited. A selective wet etching operation can be performed to remove exposed silicon layers within the word connect region as applied through the slits. The composition of the wet etching and the time applied can determine the amount of silicon removed from each side of the silicon layers to obtain a specified final thickness. In some implementations, the silicon layers have an original height in the cross-sectional view (e.g., layer thickness) within a range of 30-100 nanometer (nm) and a height after reducing the thickness within the range of 10-50 nm. By comparison, in some implementations, the original SiGe layers of the word line connect area have a height in the cross-sectional view of 10-60 nm. In some implementations, a surface of the silicon layer in the perpendicular direction, e.g., into the plane of the cross sectional view of FIG. 9 and facing the slit, is also reduced to some degree from the etching operation.

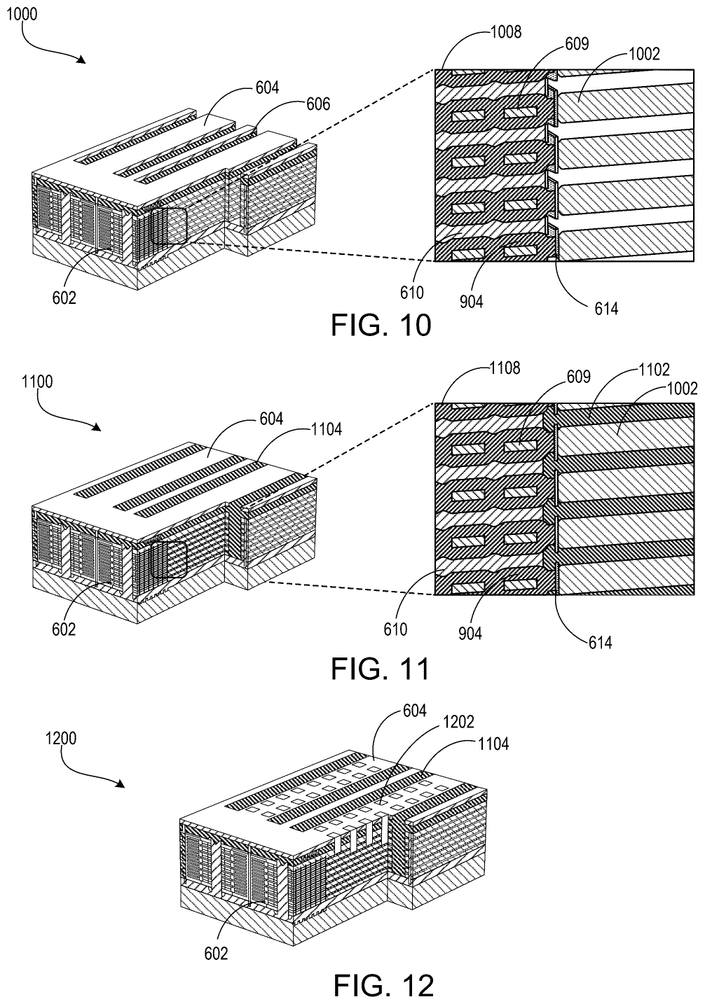

FIG. 10 is a diagram 1000 the memory cell array 602 integrated with the word line connect area 604 including a cross-sectional view of a magnified region 1008 with reduction of silicon layers 1002. As compared with the silicon layers 616 shown in FIG. 9, the reduced silicon layers 1002 are illustrated as having a decreased thickness. In particular, the silicon layers 616 had a thickness that extended into the width of the gate oxide recesses 802. By contrast, in FIG. 10, the thickness of the silicon layers 1002 is now less than the thickness of the gate oxide layer 614 between gate oxide recesses 802.

As shown in FIG. 3, the process 300 includes depositing an oxide material to fill the exposed recesses and the slits in the word connect area (314). In some implementations, the oxide material is silicon dioxide (SiO₂). However, in some other implementations, a different dielectric oxide material can be used, for example, silicon oxynitride (SiON), a composite of silicon dioxide, silicon carbide, and carbon nitride (SiCON), silicon carbon nitride (SiCN), or silicon Nitride (SiNₓ).

Thus, the former SiGe layers are replaced with an oxide layer. Additionally, an oxide layer fills the recess formed in the memory cell word lines between rows resulting in an oxide layer between the rows of memory cells that extends through the word connect area.

In some implementations, a chemical vapor deposition process is used to deposit the oxide material. Chemical vapor deposition is a deposition technique that uses gaseous precursors to fabricate thin films onto a substrate surface. In particular, in some implementations, a particular variant of chemical vapor deposition called atomic layer deposition can be used. In atomic layer deposition the precursors are alternatively supplied such that thin films can be deposited in successive layers to a desired layer thickness. In some implementations, the deposited oxide material substantially replaces the prior SiGe layer, e.g., to a thickness in the cross section within the same range as the SiGe layer of 10-60 nm.

FIG. 11 is a diagram 1100 of the memory cell array 602 integrated with the word line connect area 604 including a cross-sectional view of a magnified region 1108 with added oxide layers 1102. As illustrated in diagram 1100, the formerly recessed areas have been filled with oxide 1102. Additionally, the slits that were formed in the word line connect area have been filled with the oxide 1104. In some implementations, the top surface of the filled slits is smoothed. For example, the top surface of the word line connect area can be polished, e.g., using chemical mechanical polishing, to ensure a smooth top surface of the word line connect area.

As shown in FIG. 3, the process 300 includes forming a staircase structure for generating tier by tier word lines within the word line connect area (316). After introducing the oxide layers, the word connect area is composed of alternating layers of silicon and oxide. The combination of materials can have dry etch selectivity allowing for a dry etching operation to be used to form precise vertical holes or slits to specific layers of the word connect area. These slits can provide the tier by tier vertical portions of multiple word lines for external electrical connections. Thus, there is a slit etched to a level of the word connect area that corresponds with each row of memory cells in the memory cell array.

Dry etching, which can also be referred to as plasma etching, can be performed, for example, by positioning the word connect area within a plasma processing chamber. During a plasma processing operation, particular etch gas chemistries, selected to provide etching of particular materials, is ignited to form a plasma. Ions generated from the plasma are accelerated to the substrate. In particular, a voltage is applied to control both the energy and directionality of ions e.g., to direct ions of a particular energy vertically toward the substrate surface to perform etching of layers on the substrate to form various structures. For example, the etch gas chemistry can be switched for each layer to selectively etch the silicon and SiO₂ layers of the word line connect area. Dry etching can have greater anisotropy than wet etching allowing for precise vertical channels to be etched.

FIG. 12 is a diagram 1200 of a memory cell array 602 integrated with a word line connect area 604 including etched word line staircase openings 1202. The word line staircase openings 1202 are vertical holes of differing depths so as to align with each row of memory cells in the memory cell array 602. The depth of each of the staircase slits can depend on the number of layers in the word line connect area, and therefore the number of tiers, and the thickness of each layer as well as the thickness of any top coatings. The slits can be rectangular or square or other geometric cross section. In some implementations, slits of rectangular cross section can have cross-sectional dimensions within the range of 50-200 nm along each side.

For example, in some implementations, each staircase opening is formed with a depth to a respective reduced silicon layer 1002 of the word line connect area 604.

As shown in FIG. 3, the process 300 includes reforming the slits in the word line connect area (318). In particular, the oxide that had been deposited to fill the slit channels and fill the recessed SiGe layers can be etched to reform the slits in the word connect area. The slits can be reformed using a wet or dry etching process since the oxide filling the original slits has dry etch selectivity, e.g., depending on one or more other parameters such as duration and precision constraints. The reformed slits again provide access to each layer of the word connect area on each side of the slit.

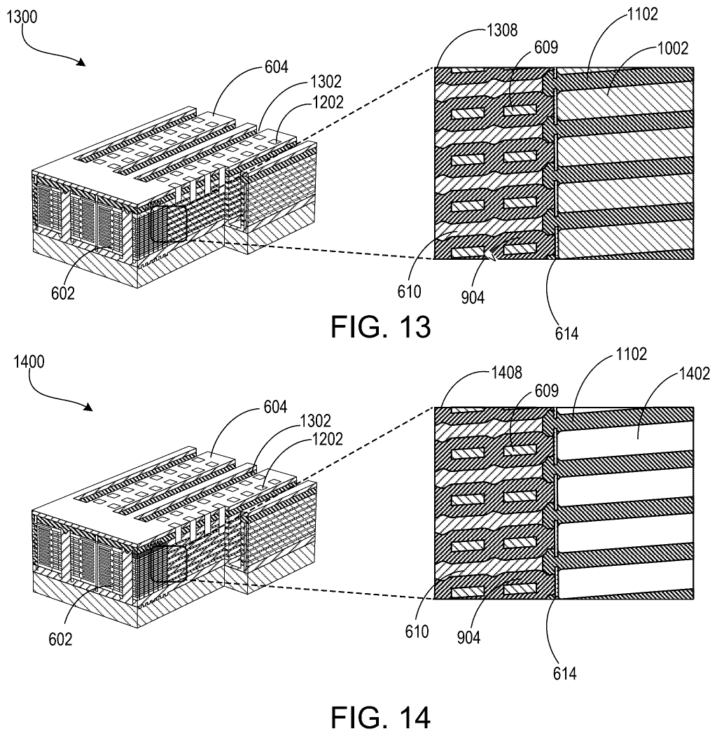

FIG. 13 is a diagram 1300 of the memory cell array 602 integrated with the word line connect area 604 including a cross-sectional view of a magnified region 1308. In particular, diagram 1300 illustrates the reformed slits 1302 in the word line connect area 604 along with the staircase openings 1202.

As shown in FIG. 3, the process 300 includes recessing the silicon layers of the word line connect area (320). In particular, a wet etching composition selected for Si can be introduced into the slits formed in the word connect region. The selective wet etching recesses the Si layers on each side of the slit while leaving the oxide layers unaffected.

FIG. 14 is a diagram 1400 of the memory cell array 602 integrated with the word line connect area 604 including a cross-sectional view of a magnified region 1408 with recessed silicon layers 1402. In diagram 1400 the word connect area 604 includes recessed layers 1402 illustrated in both the word line connect area 604 and the magnified view 1408. The oxide layers 1102 and remaining portions of the gate oxide layer 614 are unchanged.

As shown in FIG. 3, the process 300 includes recessing a portion of the gate oxide layer (322). In particular, portions of the gate oxide layer of the memory cell array are exposed by the recession of the silicon layers. The portions of the oxide layer can then be selectively etched, for example, using a wet etching process that has a composition selected to etch the gate oxide layer without etching the oxide layers of the word line connect area.

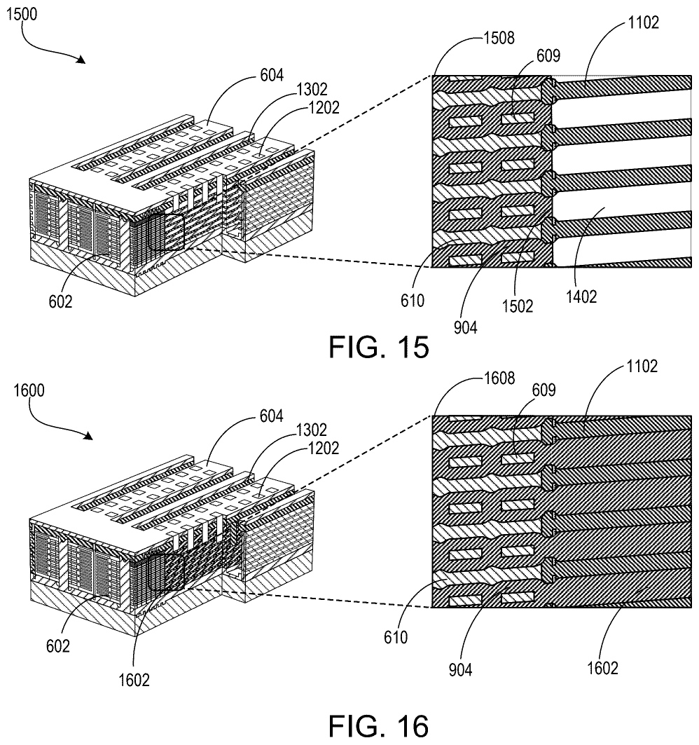

FIG. 15 is a diagram 1500 of the memory cell array 602 integrated with the word line connect area 604 including a cross-sectional view of a magnified region 1508 with gate oxide recesses 1502. In diagram 1500, the magnified region 1508 illustrates openings formed in the gate oxide layer 1502 that are aligned with the recessed layers 1402 that were previously filled by the silicon layers of the word line connect area 604. As a result, there are respective opened paths that extend from the staircase openings 1202 to the recessed layers of former silicon 1402 and through the gate oxide layer 804 to the corresponding rows of individual memory cell word lines 904.

As shown in FIG. 3, the process 300 includes depositing a conductive material to form word lines within the word line connect area (324). A metal or other conductive material such as TiN, W, Mo, or Ru can be deposited, e.g., using the slit channels, to fill the recessed layers of the word connect area and the gate oxide layer. As a result, the deposited conductive material is coupled to the memory cell word lines at each row to form a word line that extends through the word line connect region. Atomic layer deposition, as described above, can be used to deposit the conductive material into the open spaces between the layers to form the word lines and connect respective word lines to the memory cell word lines.

FIG. 16 is a diagram 1600 of the memory cell array 602 integrated with the word line connect area 604 including a cross-sectional view of a magnified region 1608 with conductive word line deposition. In diagram 1600, the conductive word line deposition electrically couples each individual memory cell word line 904 with each new word line 1602 formed within the word line connect area 604. Once externally coupled, electrical signals can be selectively sensed or applied to the word lines, and in concert with bit lines (not shown) to read or write particular memory cells of the memory cell array.

In some implementations, the staircase slits, also referred to as word line connect slits, are filled with a conductive material to electrically couple a corresponding word line with an external electrical path. The staircase slits can be filled with the same material as used in the formation of the word lines, e.g., TiN, W, Mo, or Ru. The conductive material can be deposited within the staircase slits contemporaneously with the deposition of the conductive material to form the word lines or can be performed at a later processing stage.

In some implementations, an additional oxide deposition step is performed at a point in the process following the formation of the staircase slits. In particular, since some of the staircase slits pass through multiple layers in the word line connect area, the oxide layer is added to the sidewalls of the staircase slits to prevent multiple word lines from being concurrently in contact with a single staircase slit. A later etching process can be applied to remove the deepest oxide layer adjacent to a word line (before or after deposition of the conductive material to form the word lines). As a result, each vertical staircase slit is in direct contact with a single word line to provide tier by tier word line couplings with the staircase slits.

In some implementations, the reformed slits in the word line connect area are filled with oxide after the conductive material is deposited to form the word lines. The top surface of the word line connect area can be polished, e.g., by chemical mechanical polishing, to ensure a smooth upper surface.

In addition to the embodiments of the attached claims and the embodiments described above, the following embodiments are also innovative:

Embodiment 1 is a method comprising: positioning a memory cell array on a substrate adjacent to a word line connect area, the word line connect area comprising a plurality of layers, the plurality of layers alternating between a first material and a second material; replacing at least a portion of the layers of the first material with a third material; and replacing at least a portion of the layers of the second material with a fourth material, wherein the fourth material forms word lines within the word line connect area and is electrically coupled to memory cell word lines within the memory cell array.

Embodiment 2 is the method of embodiment 1, further comprising: forming one or more slits in the word line connect area through the plurality of layers, wherein each of the one or more slits exposes a surface of each layer in the plurality of layers of the word line connect area.

Embodiment 3 is the method of any one of embodiments 1 through 2, wherein replacing at least a portion of the layers of the first material with the third material comprises: recessing at least a portion of each layer of the first material using a selective etching; reducing a dimension of at least a portion of layers of the second material; and depositing layers of the third material in recessed spaces of the first material.

Embodiment 4 is the method of any one of embodiments 1 through 3, wherein the memory cell array further comprises a surface coated with a gate oxide layer, the method further comprising: recessing portions of the gate oxide layer adjacent to the recessed portions of the layers of the first material, wherein the recessed portions of the gate oxide layer expose a surface of a memory cell word line region in the memory cell array.

Embodiment 5 is the method of any one of embodiments 1 through 4, further comprising: recessing portions of a memory cell word line region in the memory cell array; and depositing layers of the third material comprises depositing the third material in the recessed portions of the memory cell word line region and in recessed spaces of the first material.

Embodiment 6 is the method of any one of embodiments 1 through 5, wherein the depositing layers of the word line connect area forms a tier by tier stack of the first material and third material.

Embodiment 7 is the method of any one of embodiments 1 through 6, further comprising: using dry etching to form tier by tier access paths to a plurality of layers of the word line connect area.

Embodiment 8 is the method of any one of embodiments 1 through 7, wherein replacing at least a portion of the layers of the second material with the fourth material comprises: recessing at least a portion of each layer of the second material; recessing portions of a gate oxide layer of the memory cell array adjacent to the second material and to respective memory cell word lines of the memory cell array; and depositing layers of the fourth material in recessed spaces of the second material to form the word lines within the word line connect area that are electrically coupled to respective memory cell word lines.

Embodiment 9 is the method of any one of embodiments 1 through 8, wherein the first material is silicon germanium and the second material is silicon.

Embodiment 10 is the method of any one of embodiments 1 through 9, wherein the third material is a dielectric oxide material susceptible to dry etching.

Embodiment 11 is the method of any one of embodiments 1 through 10, wherein the third material comprises one of SiO2, SION, SiCON, SiCN, or SiN.

Embodiment 12 is the method of any one of embodiments 1 through 11, wherein the fourth material is an electrically conductive material.

Embodiment 13 is the method of any one of embodiments 1 through 12, wherein the fourth material comprises one of titanium nitride, tungsten, molybdenum, or ruthenium.

Embodiment 14 is a layout structure for fabricating a memory device comprising: a substrate base; a word line connect area formed on a first portion of the substrate, the word line connect area comprising a plurality of layers, the plurality of layers alternating between a first material and a second material, the word line connect area further comprising one or more slits through the plurality of layers, wherein each of the one or more slits exposes a surface of each layer in the plurality of layers; and a 3D memory cell array comprising a plurality of memory cells arranged along x, y, and z axes, the 3D memory cell array being positioned on a second portion of the substrate adjacent to the word line connect area.

Embodiment 15 is the layout structure of embodiment 14, wherein each of the one or more slits are aligned with a capacitor region of a corresponding column of memory cells.

Embodiment 16 is the layout structure of any one of embodiments 14 through 15, wherein the number of slits corresponds to a number of memory cells in a row of the memory cell array.

Embodiment 17 is the layout structure of any one of embodiments 14 through 16, further comprising one or more isolation structures formed in the word line connect area, the isolation structures isolating regions of the word line connect area corresponding to individual columns of memory cells of the memory cell array.

Embodiment 18 is the layout structure of any one of embodiments 14 through 17, wherein the first material is silicon and the second material is silicon germanium

Embodiment 19 is the layout structure of any one of embodiments 14 through 18, wherein the memory cell array further comprises a gate oxide layer coating at least a first surface of the memory cell array.

Embodiment 20 is the layout structure of any one of embodiments 14 through 19, wherein the memory cell array comprises a plurality of word lines, wherein each word line has an end face adjacent to the word line connect area.

Embodiment 21 is a method comprising: positioning a memory cell array on a substrate adjacent to a word line connect area, the word line connect area comprising a plurality of layers, the plurality of layers alternating between a first material and a second material; forming one or more slits in the word line connect area through the plurality of layers, wherein each of the one or more slits exposes a surface of each layer in the plurality of layers of the word line connect area; recessing at least a portion of each layer of the first material using a selective etching, wherein each layer is accessed using the one or more slits; recessing portions of a gate oxide layer adjacent to the recessed portions of the layers of the first material, wherein the recessed portions of the gate oxide layer expose a surface of a memory cell word line region in the memory cell array; recessing portions of the memory cell word line region in the memory cell array; reducing a dimension of at least a portion of layers of the second material; depositing layers of a third material in the recessed portions of the memory cell word line region and in recessed spaces of the first material; recessing at least a portion of each layer of the second material; recessing portions of the gate oxide layer of the memory cell array adjacent to the second material and to respective memory cell word lines of the memory cell array; and depositing layers of a fourth material in recessed spaces of the second material to form word lines within the word line connect area, each word line being electrically coupled to a corresponding memory cell word line.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

1. A method comprising:
positioning a memory cell array on a substrate adjacent to a word line connect area, the word line connect area comprising a plurality of layers, the plurality of layers alternating between a first material and a second material;
replacing at least a portion of the layers of the first material with a third material; and
replacing at least a portion of the layers of the second material with a fourth material, wherein the fourth material forms word lines within the word line connect area and is electrically coupled to memory cell word lines within the memory cell array.

2. The method of claim 1, further comprising:
forming one or more slits in the word line connect area through the plurality of layers, wherein each of the one or more slits exposes a surface of each layer in the plurality of layers of the word line connect area.

3. The method of claim 2, wherein replacing at least a portion of the layers of the first material with the third material comprises:
recessing at least a portion of each layer of the first material using a selective etching;
reducing a dimension of at least a portion of layers of the second material; and
depositing layers of the third material in recessed spaces of the first material.

4. The method of claim 3, wherein the memory cell array further comprises a surface coated with a gate oxide layer, the method further comprising:
recessing portions of the gate oxide layer adjacent to the recessed portions of the layers of the first material, wherein the recessed portions of the gate oxide layer expose a surface of a memory cell word line region in the memory cell array.

5. The method of claim 4, further comprising:
recessing portions of a memory cell word line region in the memory cell array; and
depositing layers of the third material comprises depositing the third material in the recessed portions of the memory cell word line region and in recessed spaces of the first material.

6. The method of claim 5, wherein the depositing layers of the word line connect area forms a tier by tier stack of the first material and third material.

7. The method of claim 5, further comprising:
using dry etching to form tier by tier access paths to a plurality of layers of the word line connect area.

8. The method of claim 2, wherein replacing at least a portion of the layers of the second material with the fourth material comprises:
recessing at least a portion of each layer of the second material;
recessing portions of a gate oxide layer of the memory cell array adjacent to the second material and to respective memory cell word lines of the memory cell array; and
depositing layers of the fourth material in recessed spaces of the second material to form the word lines within the word line connect area that are electrically coupled to respective memory cell word lines.

9. The method of claim 1, wherein the first material is silicon germanium and the second material is silicon.

10. The method of claim 1, wherein the third material is a dielectric oxide material susceptible to dry etching.

11. The method of claim 10, wherein the third material comprises one of SiO2, SiON, SiCON, SiCN, or SiN.

12. The method of claim 1, wherein the fourth material is an electrically conductive material.

13. The method of claim 12, wherein the fourth material comprises one of titanium nitride, tungsten, molybdenum, or ruthenium.

14. A layout structure for fabricating a memory device comprising:
a substrate base;
a word line connect area formed on a first portion of the substrate, the word line connect area comprising a plurality of layers, the plurality of layers alternating between a first material and a second material, the word line connect area further comprising one or more slits through the plurality of layers, wherein each of the one or more slits exposes a surface of each layer in the plurality of layers; and
a 3D memory cell array comprising a plurality of memory cells arranged along x, y, and z axes, the 3D memory cell array being positioned on a second portion of the substrate adjacent to the word line connect area.

15. The layout structure of claim 14, wherein each of the one or more slits are aligned with a capacitor region of a corresponding column of memory cells.

16. The layout structure of claim 14, wherein the number of slits corresponds to a number of memory cells in a row of the memory cell array.

17. The layout structure of claim 14, further comprising one or more isolation structures formed in the word line connect area, the isolation structures isolating regions of the word line connect area corresponding to individual columns of memory cells of the memory cell array.

18. The layout structure of claim 14, wherein the first material is silicon and the second material is silicon germanium.

19. The layout structure of claim 14, wherein the memory cell array further comprises a gate oxide layer coating at least a first surface of the memory cell array.

20. The layout structure of claim 14, wherein the memory cell array comprises a plurality of word lines, wherein each word line has an end face adjacent to the word line connect area.

21. A method comprising:
positioning a memory cell array on a substrate adjacent to a word line connect area, the word line connect area comprising a plurality of layers, the plurality of layers alternating between a first material and a second material;
forming one or more slits in the word line connect area through the plurality of layers, wherein each of the one or more slits exposes a surface of each layer in the plurality of layers of the word line connect area;
recessing at least a portion of each layer of the first material using a selective etching, wherein each layer is accessed using the one or more slits;
recessing portions of a gate oxide layer adjacent to the recessed portions of the layers of the first material, wherein the recessed portions of the gate oxide layer expose a surface of a memory cell word line region in the memory cell array;
recessing portions of the memory cell word line region in the memory cell array;
reducing a dimension of at least a portion of layers of the second material;
depositing layers of a third material in the recessed portions of the memory cell word line region and in recessed spaces of the first material;
recessing at least a portion of each layer of the second material;
recessing portions of the gate oxide layer of the memory cell array adjacent to the second material and to respective memory cell word lines of the memory cell array; and
depositing layers of a fourth material in recessed spaces of the second material to form word lines within the word line connect area, each word line being electrically coupled to a corresponding memory cell word line.
